(19) United States
(12) Patent Application Publication
(10) Pub. No.: US 2009/0104774 A1
(43) Pub. Date: Apr. 23, 2009

(54) METHOD OF MANUFACTURING A SEMICONDUCTOR DEVICE

(75) Inventors: Yukiko Furukawa, Veldhoven (NL); John MacNeil, Cardiff (GB)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/815,007

(22) PCT Filed: Jan. 25, 2006
(86) PCT No.: PCT/IB2006/050269

§ 371 Date: Dec. 2, 2008

Related U.S. Application Data
(60) Provisional application No. 60/647,991, filed on Jan. 27, 2005.

(51) Int. Cl. H01L 21/44

(52) U.S. Cl. 438/680; 438/795; 257/E21.478

(57) ABSTRACT

This invention relates to a method of manufacturing a semiconductor device. In this method, a semiconductor device is provided comprising a substrate (10), the substrate (10) being covered with a low-k precursor layer (20) having a surface (25). After this step, a partial curing step is performed in which a dense layer (30) is formed at or near the surface (25) of a low-k precursor layer (20). This dense layer (30) can act as a protective layer (30). The low-k precursor material (20) is chosen from a group of materials having the property that they are applicable in a non-cured or partially cured state. The main advantage of this method is that no separate protective layer (30) needs to be provided to the low-k precursor layer (20), because the dense layer (30) is formed out of the low-k precursor layer (20) itself. The dense layer (30) therefore has a good adhesion to the low-k precursor layer (20).

This invention relates to methods of manufacturing semiconductor devices.

In the manufacture of semiconductor devices it is usual to lay down layers of dielectric material through which trenches and/or vias may be etched to provide interconnections between active devices formed in the semiconductor wafer substrate. As the device dimensions become smaller, there is a significant drive to reduce the dielectric constant of the dielectric material forming the dielectric layers, and these materials have brought with them a number of problems. For example, selectivity-related issues may crop up during etching, and also hydrogen, which is often given off by such materials, can be damaging to other layers, which are subsequently laid down. To overcome these and other problems well known in the art, the practice has been to lay down a ‘hard mask’ layer on the material. However, the current Applicants have determined that often there are adhesion problems between such hard masks and the dielectric layer, particularly as it may be necessary to lay down this layer prior to curing of the dielectric layer-forming material.

Another problem is that advanced low-k dielectric materials achieve their low k-value by being porous. When etching takes place through the porous material, cavities can be exposed, or occur, at the sidewalls of the etch formations. U.S. Pat. No. 6,528,409 shows an attempt to overcome this problem by etching through the dielectric material in its uncured state, after a hard mask has been deposited on top of the uncured material, filling the resultant recess with conductive material and then subjecting the dielectric material to a full cure. Such a process introduces the adhesion problems set out above and further requires that there is no dimensional change in the dielectric material upon curing. This will not generally be the case.

U.S. Pat. No. 6,531,755 describes the deposition of a porous material on the substrate. The porous material is baked and then a protective layer is deposited thereon. Subsequently, etching takes place and the sidewalls of the resultant recess or formation are processed to remove the microcavities arising from the porosity of the material.

The invention comprises a method of manufacturing a semiconductor device, including the steps of:

a) providing a substrate;
b) applying a layer of uncured, or only partially cured, dielectric material to the substrate, the layer having an exposed surface, and the material being selected from a group having a low dielectric constant in its cured state; and
c) curing the dielectric material, characterized in that the curing step consists of an initial partial cure for forming a dense layer near to or at the exposed surface, said dense layer acting as a protection layer during at least one further manufacturing step in the dielectric material, and a subsequent cure for curing the bulk material.

The use of an initial partial cure to form the dense layer overcomes the adhesion problems mentioned above. It also enables processing of the uncured bulk of the material, providing advantages as regards selectivity and lack of porosity in at least certain embodiments. It also removes, in most cases at least, the need to supply separate precursors or spin-on-materials to form the additional layer, as is required in the above mentioned prior art.

In at least some embodiments, the at least one manufacturing step may take place between the initial partial cure and the subsequent cure. For example, the manufacturing step may include forming a recess or formation in the layer, the recess or formation having walls which are at least in part defined by the material of the layer. Typically, the recess or formation will be formed by etching, in which case the dense layer may be pre-etched to form a mask for the etching step. Preferably, the subsequent cure takes place after forming the recess or formation. Electrically conductive material may preferably be deposited in the recess or formation after the subsequent cure, although if there is no significant change in dimension of the layer during curing, it may be deposited prior to the subsequent cure.

The material may be one which can be rendered porous by curing and which is rendered porous by the subsequent cure.

The material may comprise a SiCo:H-type material, which may be applied using a CVD technique. Examples of such materials are ORION® or low-k FLOWFILL®, as referred to below. These materials are relatively easy to deposit and can usually be cured by the appropriate application of plasma in the CVD tool, as indicated below.

The applied CVD-technique may be chosen from P-CVD, LT-CVD, AP-CVD and RT-CVD.

The step of partially curing the material may be performed in a CVD tool and the following process conditions may be used:
H₂-Flow=10 to 10,000 sccm, process chamber pressure=1 to 10 Torr, RF power=10 W to 10 kW, RF frequency=100 KHz to 100 MHz, platen temperature=300 to 600° C., electrode spacing is 5 to 500 mm and plasma time=1 second to 3 minutes. In a particularly preferred embodiment the process conditions may be:
H₂-Flow=1600 sccm, process chamber pressure=4 Torr, RF power=2 kW, RF frequency=13.56 MHz, platen temperature=400° C., electrode spacing is 20 mm and plasma time=15 seconds.

Where a recess or formation is formed, a barrier layer may be applied at least to the sidewalls of the recess or formation, and where such a recess or formation is filled, a capping layer may be applied at least onto the conductive material.

These and other aspects of the method according to the invention will be further elucidated and described with reference to the drawings, in which:

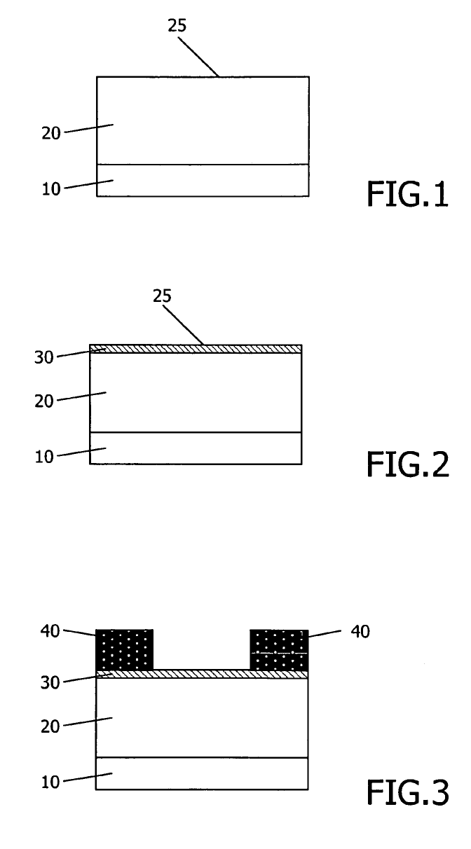

FIGS. 1-10 illustrate a semiconductor device in different stages of the method according to the invention;

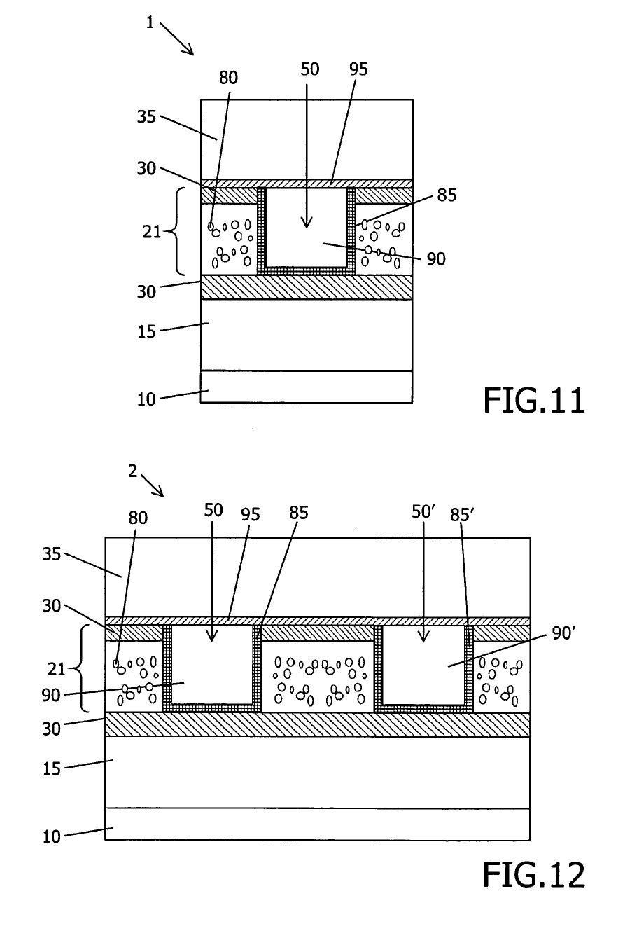

FIG. 11 illustrates a first embodiment of the semiconductor device according to the invention;

FIG. 12 illustrates a second embodiment of the semiconductor device according to the invention.

In relation to the appended drawings, embodiments of the present invention are described in detail later on. However, it will be apparent that a person skilled in the art can imagine several other equivalent embodiments (or combine the embodiments explicitly given in this specification) or other ways of executing the present invention, the spirit and scope of the present invention being limited only by the terms of the appended claims. All drawings are intended to illustrate some aspects and embodiments of the present invention. Most aspects are presented in a simplified way for reason of clarity. Not all alternatives and options are shown and, therefore, the invention is not limited to the content of the given drawings.

FIG. 1 illustrates a semiconductor device in a preliminary stage of one embodiment of the invention. In this stage the semiconductor device comprises a substrate 10, which substrate 10 is covered with a precursor layer 20 having a surface 25. The material of layer 20 is of the type which has a low dielectric constant (low-k) when cured. In its precursor, or uncured, form it will often have a high k. The term “low-k” refers to dielectric constant or k-values preferably below 3.0. The substrate 10 may comprise a wafer with active devices (e.g. transistors, diodes, etc), and/or also other layers, which in turn may comprise conductor structures (e.g. interconnections, contacts and vias). The wafer may comprise silicon, germanium, strained-silicon, buried oxide layers, glass and the like. The low-k precursor layer 20 may be applied using Chemical Vapor Deposition (CVD) techniques such as PE-CVD, LT-CVD, AP-CVD and RT-CVD. PE-CVD stands for Plasma-Enhanced CVD. LT-CVD stands for Low-Temperature CVD. AP-CVD stands for Atmospheric-Pressure CVD. RT-CVD stands for Rapid-Temperature CVD. It must be noted that different companies may use different designations for the various types of CVD-techniques. Also, there may be more CVD-variants which can suitably be used in the deposition of the low-k precursor material. The low-k precursor material 20 is applied in a non-cured, or only partially cured, state and, in particular, is not porous.

FIG. 2 illustrates a semiconductor device in a further stage of the method. In this stage a partial curing step is performed in which, near the surface 25, a dense layer 30 is formed out of the low-k precursor layer 20. This layer does not chemically interact with photoresist and may be a barrier between layer 20 beneath it and the photoresist. Furthermore, it etches more slowly than the precursor material 20 beneath it and thereby can act as a protective layer 30. In one embodiment these characteristics result from a carbon and/or nitrogen depletion as a result of a hydrogen plasma treatment.

Thus, the fact that the material is applied in a non-cured state enables conversion of the low-k precursor material into a dense layer 30 at the surface 25 by means of partial curing in this stage of the method. Certain CVD-SiCO:H-type low-k precursor materials fulfill the requirement mentioned above. In particular a low-k precursor material used to form one or more of the following low-k dielectrics has been found to be applicable: Orion®, Flowfill® and low-k Flowfill®, each of which is a dielectric material depositable in accordance with processes of Trikon Technologies, Inc., which are defined in, respectively:
ORION: GB 2,355,992B
FLOWFILL: GB 731,928B/U.S. Pat. No. 5,874,367B/U.S. Pat. No. 6,287,989B
LOW-K FLOWFILL: GB 2,331,626B/U.S. Pat. No. 6,242,366B

The contents of these cases are incorporated by reference.

The application of such a precursor for these or other SiCo:H-type materials in a non-cured state is not obtained automatically and may be in contradiction with the teaching of how to obtain these or other low-k dielectrics, but in any case may be advantageously incorporated in the processes otherwise used to obtain these dielectrics. For example, preferable process conditions in a CVD-tool for the deposition of a low-k precursor to form Orion® suitable for this invention are as follows:
400 sccm O₂, 700 sccm tetramethylsilane, 2400 sccm N₂ with 500 W of 13.56 MHz RF power (for a 200 mm wafer) being applied to an opposing showerhead located at 20 mm, at a chamber pressure of 2 Torr and a wafer platen temperature of 35° C.

It should be understood that these process conditions may be varied by experimentation within the teaching of this disclosure.

Any suitable precursor gas, gasses or vapors may be used to deposit a precursor layer 20 that may be processed by means of the teachings of this disclosure. In the example given above, a low-k dielectric precursor layer 20 is formed that contains silanol, and this may be achieved by the oxidation of an organosilane (for example an alkylsilane like methylsilane, tetra-alkylsilane, trimethysilane or tetramethylsilane), or organosiloxane (for example tetramethyldisiloxane).

Partial curing to form dense layer 30 that acts as a protection layer during at least one further manufacturing step is not known in the prior art. Said partial curing also may need different conditions (other than simply time) as compared to a full-curing step. Partial curing of Orion® can, for example, be performed using the following process conditions:
2 kW of 13.56 MHz RF power applied to a showerhead close-coupled to an opposing substrate platen at 400° C. in a low-volume single-wafer process chamber at 4 Torr hydrogen pressure (1600 sccm of hydrogen supplied) for 15 seconds.

It should be understood that this partial cure is sufficient to render the surface chemically stable to avoid interaction with photoresist and enable the surface to act as a barrier between the photoresist and the layer beneath dense layer 30 to give the surface a slower etch rate than the bulk (uncured) low-k material during subsequent patterning. The partial cure process will therefore preferably be the minimum processing necessary to achieve these characteristics.

The mechanism behind partial curing is as follows. During partial curing, the H₂-plasma depletes carbon and nitrogen at the surface of the non-cured CVD low-k material and densifies it. This will create SiO₂-like material at the surface. Thus, the dense layer 30, which is formed during this step, comprises SiO₂-like material.

FIG. 3 illustrates a semiconductor device in a subsequent stage of the method. In this stage a patterned photoresist layer 40 is applied on top of the dense layer 30 of the semiconductor device. The dense layer (protection layer) 30 is generally needed as an anti-reflection layer for the photoresist layer 40 in order to prevent chemical reaction between the photoresist layer 40 and the bulk of the low-k precursor layer 20 and may also be used for getting etch selectivity with respect to the resist/mask. The anti-reflection layer protects the photoresist layer 40 against reflections of light (preferably UV-light) from lower layers in the semiconductor device being manufactured. Reflected light may interfere with light coming from a light source, resulting in a deterioration of patterns in the photoresist layer.

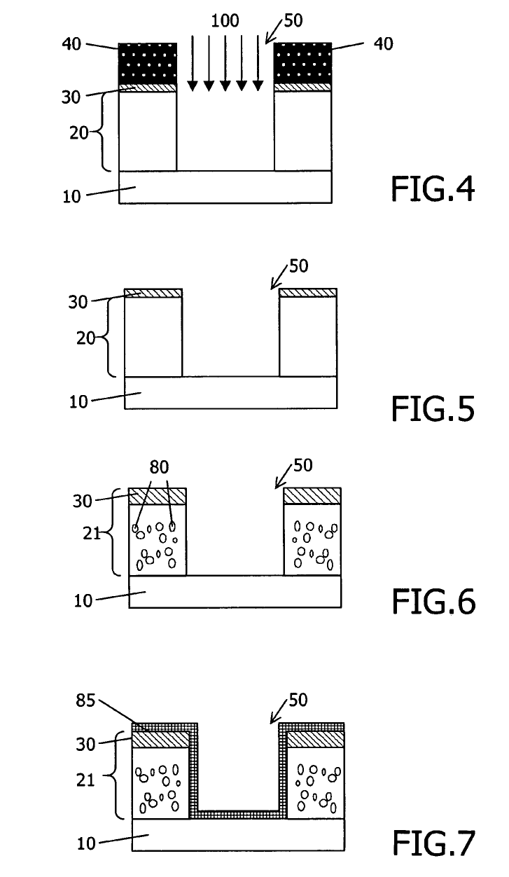

FIG. 4 illustrates a semiconductor device in a still further stage of the method. In this stage a recess 50 is formed using the patterned photoresist layer 40, the recess 50 extending through the dense layer 30 into the low-k precursor layer 20. The recess 50 may be formed by means of dry etching, for instance using a plasma 100 in a tool. The plasma 100 may comprise chemistries like Ar/CₓH_{y}F_{z}/O₂ (where x,y,z>=0), but other chemistries are also possible.

FIG. 5 illustrates a semiconductor device in another stage of the method. In this stage of the method the photoresist layer 40 is stripped. In the prior art, stripping is also referred to as “ashing”. Stripping may be performed with a plasma comprising a chemistry. Resist stripping is a technique well-known to a person skilled in the art. More information on resist stripping can be found in [“Dry etching for VLSI” by Λ. J. van Roosmalen, J. Λ. G. Baggerman, S. J. H. Brader, Plenum press, New York (1991) ISBN 0-306-43835-6, p 125˜128].

FIG. 6 illustrates a semiconductor device in another stage of the method. In this stage the semiconductor device is further cured. In the prior art various curing methods are known. One class of methods uses heat treatment and another class of methods uses plasma treatment in association with heat. Other cures are known, e.g. e-beam. The best-known process conditions for a plasma treatment for the invention disclosed here are:
H₂-flow=1600 sccm, chamber pressure=4 Torr, RF power=180 seconds at 1 kW followed by 70 seconds at 2.5 kW at an RF frequency of 13.56 MHz, platen temperature=400° C.

Λ further important characteristic of a plasma cure is that the plasma power applied is sufficient to cause the low-k precursor layer 20 to convert to a low-k dielectric 21. For example, as in the case of ORION®, when it is fully cured a very low k-value may be gained by creating porosity as described in WO03/044843. Not all suitable materials will be rendered porous in the finalcure. For example low-k FlowFill® provides a low k-value, without porosity. If insufficient power is applied during either partial or full cure, then the dielectric may not become porous during full cure. The power level can be derived experimentally and will be a function of chamber architecture, electrode size, etc. It is also self-evident that if a very low power is applied, or if heating of the wafer is applied before the plasma, then in effect a thermal cure is practiced.

If a sufficiently high plasma power is applied, the partially cured low-k precursor material will cure to form a lower-k material. In this case, for wafer sizes of 200 mm and above, in a close-coupled single wafer reactor, 2 kW is a practical minimum to be observed.

More details on a suitable curing technique and required process conditions can be found in U.S. Pat. No. 6,653,247 B2, which is incorporated herein by reference.

It may also be possible to carry out the fullcure at different stages of the methods (e.g. after barrier deposition and/or after chemical-mechanical-polishing). However, if the full cure causes dimensional change in the layer 20, it may be necessary to cure prior to metallization of the recess 50, because otherwise delamination may occur. In an example of a curing process, silanol, contained within the low-k precursor layer 20, releases water, but organic materials may also be released. Furthermore, Si—CH₃ bonds are converted to Si—CH₂—Si bonds, creating spacious structures. This will create pores 80 in the low-k precursor layer 20, turning it into a porous (low-k) dielectric layer 21. Preferably these pores are small, such as less than 10 Å. Especially SICO:H-type materials provide pores having that size.

FIG. 7 illustrates a semiconductor device in another stage of the method according to the invention. In this stage a barrier layer 85 may be applied at least into the recess 50. The barrier material 85 may comprise materials like tantalum (Ta) or titanium (Ti) or titanium nitride (TiN), which are applied by means of PVD or metal organic CVD techniques. An alternative material is tungsten carbon nitride (WCN) being applied by means of ALD-techniques. However, the barrier material layer 85 may also comprise a layer stack, such as a layer of tantalum nitride with a layer of tantalum (both layers may also be applied using PVD-techniques).

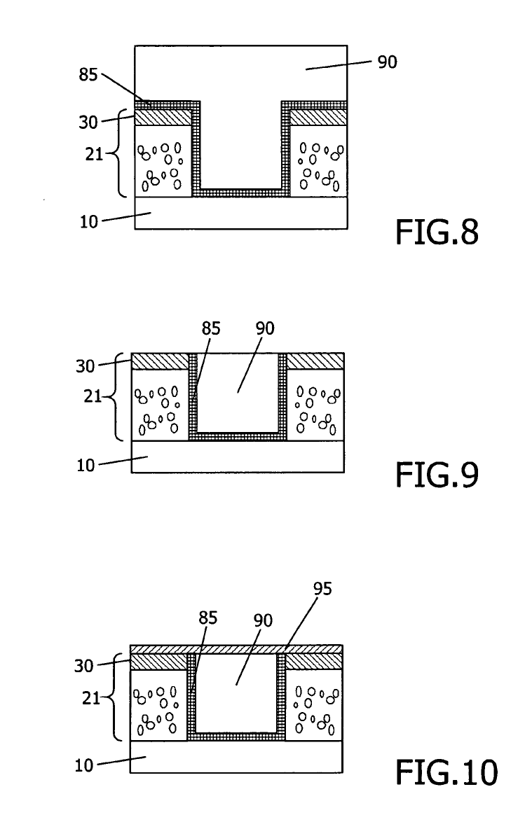

After the barrier layer 85 has been applied (FIG. 8), a conductor 90 is applied at least into the recess 50. The conductor 90 may for instance comprise materials like copper or aluminum. The main function of the barrier material is to encapsulate the conductive materials 90, which should not diffuse through the dielectric into circuitry of the semiconductor device, because they would harm the reliability of the semiconductor device. A known example of such a conductive material is copper. In case other materials are used, like for instance aluminum, the barrier layer 85 might be omitted.

FIG. 9 illustrates a semiconductor device in another stage of the method. In this stage, the semiconductor device is planarized using, for example, a chemical-mechanical-polishing step (also known as CMP). In this particular example, the CMP process stops at the dense layer 30 and it is a desirable characteristic of the dense layer 30 that it is a good CMP stop layer, and therefore an additional CMP stop layer may not be required. However, it is an option to remove the dense layer 30 as well.

FIG. 10 illustrates a semiconductor device in another stage of the method. In this stage, an optional capping layer 95 is provided onto the semiconductor device. This may be a capping layer 95 covering large areas or a patterned capping layer covering only those areas where a conductor 90 is located. The capping layer 95 may be needed for completing the encapsulation of the conductor 90 by the barrier layer 85. In case a contact should be connected, from above, to the conductor 90, the capping layer can be patterned so as to expose the conductor 90, thereby enabling electrical contact to be made from above. The capping layer may comprise silicon nitride (Si₃N₄) and silicon carbide (SiC), but other materials are also possible.

It must further be noted that, although in this particular example the conductor 90 resembles a conducting line (the recess being a trench) running perpendicularly to the cross-section in FIG. 9, it may also be a contact or via. In that case, the recess 50 must be a hole in the low-k precursor layer 20 (FIG. 5).

Furthermore, it is also possible to perform the method such that a conducting line and a contact are formed at the same time. This can be achieved in various ways. One way is by performing the step of forming the recess in the low-k precursor material 20 in two different steps (e.g. after having formed two dielectric layers) using different masks, while keeping the rest of the method the same. A person skilled in the art may easily come up with alterations in the order in which the steps are performed.

After the stage illustrated in FIG. 10, the semiconductor device is ready for further processing, such as forming subsequent metallization and/or contact/via layers, packaging, etc. All these steps are known to a person skilled in the art.

FIG. 11 illustrates a first embodiment of the semiconductor device. This semiconductor device 1 comprises a substrate 10, a dielectric layer 21 applied to the substrate 10, the dielectric layer 21 having a recess 50, the recess 50 having walls defined by the dielectric layer 21, the recess 50 being filled with a conductor 90, the conductor 90 being embedded in an (optional) barrier layer 85 at least on sidewalls of the conductor 90. The semiconductor device 1 in this embodiment further comprises dense layers 30. The dense layers 30 may comprise SiO₂-type materials. In this particular example, the conductor 90 (e.g. a copper line) is provided with a capping layer 95. In some embodiments, this capping layer 95 may be absent or partially removed (e.g. for allowing a contact to be in electrical contact with a line). In this particular example, layers 15, 35 do not comprise conductors, although in other embodiments this is very well possible.

FIG. 12 illustrates a second embodiment of the semiconductor device. The semiconductor device 2 comprises all the elements of the first embodiment of the semiconductor device 1, but the dielectric layer 21 additionally comprises a further recess 50′ at a distance from the recess 50, the further recess 50′ having further walls defined by the dielectric layer 21, the further recess 50′ being filled with a further conductor 90′, the further conductor 90′ being embedded in a further barrier layer 85′ at least on sidewalls of the further conductor 90′.

Please note that the description is meant to support rather than limit the claims. Many variations to the illustrations shown are possible, but have not been included in the discussion in order to keep the invention clear and concise.

1. A method of manufacturing a semiconductor device including the steps of: a) providing a substrate 10; b) applying a layer of uncured, or only partially cured, dielectric material to the substrate, the layer having an exposed surface, and the material being selected from a group having a low dielectric constant in its cured state; and c) curing the dielectric material, characterized in that the curing step consists of an initial partial cure for forming a dense layer in the dielectric material near to or at the exposed surface, said dense layer acting as a protection layer during at least one further manufacturing step, and a subsequent cure for curing the bulk material.

2. A method as claimed in claim 1, wherein at least one manufacturing step takes place between the initial partial cure and the subsequent cure.

3. A method as claimed in claim 2, wherein the manufacturing step includes forming a recess or formation in the layer, the recess or formation having walls at least in part defined by the material of the layer.

4. A method as claimed in claim 3, wherein the recess or formation is formed by etching.

5. A method as claimed in claim 4, wherein the dense layer is pre-etched to form a mask for the etching step.

6. A method as claimed in claim 3, wherein the subsequent cure takes place after forming the recess or formation.

7. A method as claimed in claim 6, wherein the electrically conductive material is deposited in the recess or formation after the subsequent cure.

8. A method according to claim 3, characterized in that the method further comprises the step of applying a barrier layer at least on the sidewalls of the recess or formation of the semiconductor device.

9. (canceled)

10. A method as claimed in claim 1, wherein the material is one which can be rendered porous by curing and is rendered porous by the subsequent cure.

11. A method according to claim 1, characterized in that the material comprises a SiCO:H-type material applied using the CVD-technique.

12. A method according to claim 11, characterized in that the low-k precursor material being applied comprises a precursor material of Orion™.

13. A method according to claim 11, characterized in that the low-k precursor material being applied comprises a precursor material of Low-K Flowfill™.

14. A method according to claim 11, characterized in that the applied CVD-technique is one of PE-CVD. LT-CVD, LT-CVD, AP-CVD and RT-CVD.

15. A method according to claim 1, characterized in that the step of partially curing the material is performed in a CVD-tool.

16. A method according to claim 15, characterized in that the step of partially curing the material is performed in a CVD-tool under the following process conditions:
H₂-HoW=10 to 10,000 sccm, process chamber pressure=1 to 10 Torr., RF power=10 W to 10 kW, RF frequency=100 KHz to 100 MHz, platen temperature=300 to 600° C., electrode spacing is 5 to 500 mm and plasma time=1 second to 3 minutes.

17. A method according to claim 16, characterized in that the step of partially curing the precursor material is performed in a CVD-tool under the following process conditions:
H₂—FI0W=1600 sccm, process chamber pressure=4 Torr, RF power=2 kW, RF frequency=13.56 MHz, platen temperature=400° C., electrode spacing is 20 mm and plasma time=15 seconds.

18. A method of manufacturing a semiconductor device including the steps of:
a) providing a substrate;
b) applying a layer of uncured, or only partially cured, dielectric material to the substrate, the layer having an exposed surface, and the material being selected from a group having a low dielectric constant in its cured state; and
c) curing the dielectric material, characterized in that the curing step consists of an initial partial cure for forming a dense layer in the dielectric material near to or at the exposed surface, said dense layer acting as a protection layer during at least one further manufacturing step, and a subsequent cure for curing the bulk material; and
wherein at least one manufacturing step takes place between the initial partial cure and the subsequent cure.
wherein the manufacturing step includes forming a recess or formation in the layer, the recess or formation having walls at least in part defined by the material of the layer; and
d) applying a barrier layer at least on the sidewalls of the recess or formation of the semiconductor device.
